(19) United States
(12) Patent Application Publication
(10) Pub. No.: US 2020/0402863 A1
(43) Pub. Date: Dec. 24, 2020

(54) METHODS AND SYSTEMS FOR DEFINING A PROCESS WINDOW

(71) Applicant: Carl Zeiss SMT GmbH, Oberkochen (DE)

(72) Inventors: Jagdish Chandra Saraswatula, Singapore (SG); Raghavendra Hanumantha Nayak, Pleasanton, CA (US); Thomas Korb, Schwaebisch Gmuend (DE)

(21) Appl. No.: 16/564,683

(22) Filed: Sep. 9, 2019

(51) Int. Cl. H01L 21/66; G06T 7/00; G06T 7/11; H01L 21/67

(52) U.S. Cl. CPC H01L 22/12; G06T 7/0006; G06T 2207/30148; H01L 21/67288; G06T 2207/10061; G06T 7/11

(57) ABSTRACT

An optical tool is used to define critical regions in a wafer including a plurality of dies manufactured with different process parameters. An mSEM is used to scan the critical regions.

### FIELD

The disclosure relates to methods and systems for wafer inspection, for example for defining a process window for manufacturing semiconductor chips.

### BACKGROUND

Process window definition is an aspect in semiconductor chip manufacturing and refers to determining process parameters for various processing steps in the production process of such chips. Among these manufacturing steps there are usually a number of lithography steps where a photoresist is applied to the wafer and then illuminated and developed to define structures to be formed, which are then manufactured by techniques like etching, material deposition etc. For this illumination, a lithography scanner is often used. Within the process window definition, defining a range of focus and dose (also referred to as exposure, light intensity over time) of the lithography scanner has an influence on the critical dimensions (CD). The critical dimension are one or more defined dimensions in a structure the size of which gives information regarding the quality of a process step, for example a line width or a diameter of vias. Other steps influencing the critical dimension include etching, pre-bake and post-bake, chemical mechanical polishing (CMP) etc.

For process window definition, usually different dies on a semiconductor wafer are exposed with different doses and/or focus conditions of the lithography scanner and then processed to form structures. This is also referred to as modulation of dose and focus. The dies are then subjected to inspection and defect analysis with respect to the planned process window. Based on the defectivity analysis operating parameters (dose and focus) for the lithography scanner is decided which is then used for high volume manufacturing centering the process on the planned process window.

A typical test wafer, also referred to as process window wafer or focus-exposure matrix used for this process window definition consists of dies with at least 4 to 5 different values of focus and 4 to 5 different values of dose. Remaining dies are typically subjected to perceived nominal process window conditions, i.e. conditions which for example according to previous experience would result in the planned process window.

In many known approaches for the above-mentioned defectivity analysis, an optical inspection using bright field or dark field approaches is used to identify possible defects or other regions of interest in the dies to be examined more closely, and then these areas are further examined using scanning electron microscopy (SEM). Shrinking critical dimensions can make it difficult for optical tools like microscopes for the optical inspection to correctly identify defects, and this in conventional approaches leads to multiple repetitions of optical inspections followed by SEM measurements. This in turn leads to a long duration of the process window determination.

### SUMMARY

In a general aspect, a method includes: providing a wafer including a plurality of dies including structures, where different dies have been manufactured using different process parameters; defining critical regions on the dies using an optical tool; and scanning the critical regions using a multi-beam scanning electron microscope using a plurality of scanning beams simultaneously.

In a general aspect, an inspection system includes: an optical tool configured to define critical regions in a wafer including a plurality of dies including structures, wherein different dies are manufactured using different process parameters; and a multi-beam scanning electron microscope using a plurality of scanning beams in parallel configured to scan the critical regions.

In a general aspect, a method includes: providing a plurality of wafers including structures, where different wafers have been manufactured using different process parameters; defining critical regions on the wafers using an optical tool; and scanning the critical regions using a multi-beam scanning electron microscope using a plurality of scanning beams simultaneously.

In a general aspect, a method includes: using an optical tool to define critical regions on a plurality of dies of a wafer, the plurality of dies comprising structures, different dies manufactured via different process parameters an optical tool; and simultaneously using a plurality of scanning beams of a multi-beam scanning electron microscope to scan the critical regions.

In a general aspect, an inspection system includes an optical tool configured to define critical regions in a wafer including a plurality of dies comprising structures, different dies manufactured via different process parameters; and a multi-beam scanning electron microscope configured to simultaneously use a plurality of scanning beams to scan the defined critical regions.

In a general aspect, a method includes: using an optical tool to define critical regions on a plurality of wafers, the wafers comprising structures, different wafers manufactured via different process parameters; and simultaneously using a plurality of scanning beams of a multi-beam scanning electron microscope to scan the critical regions.

In a general aspect, one or more machine-readable hardware storage devices include instructions that are executable by one or more processing devices to perform operations comprising a method disclosed herein.

In a general aspect, a system includes: one or more processing devices; and one or more machine-readable hardware storage devices comprising instructions that are executable by the one or more processing devices to perform operations a method disclosed herein.

The above summary is merely intended to give a brief overview over some embodiments and is not to be construed as limiting in any way. In particular, other embodiments may include other features than the ones identified above.

### BRIEF DESCRIPTION OF THE DRAWINGS

FIG. 1 shows a system according to some embodiments.

FIG. 2 is a flowchart illustrating methods according to some embodiments.

### DETAILED DESCRIPTION

In the following, various embodiments will be described in detail referring to the attached drawings. These embodiments are to be taken as illustrative examples only and are not to be construed as limiting the scope of the disclosure.

While embodiments may be described as including a plurality of features or elements, this is only an example, and in other embodiments, some of these features may be omitted and/or may be replaced by alternative features or elements. Features ore elements from different embodiments may be combined to form further embodiments. Variations and modifications described with respect to one of the embodiments are also applicable to other embodiments and will therefore not be described repeatedly.

Apart from the features and elements explicitly shown and described, other features or elements, for example features or elements used in conventional process window definition, may be used.

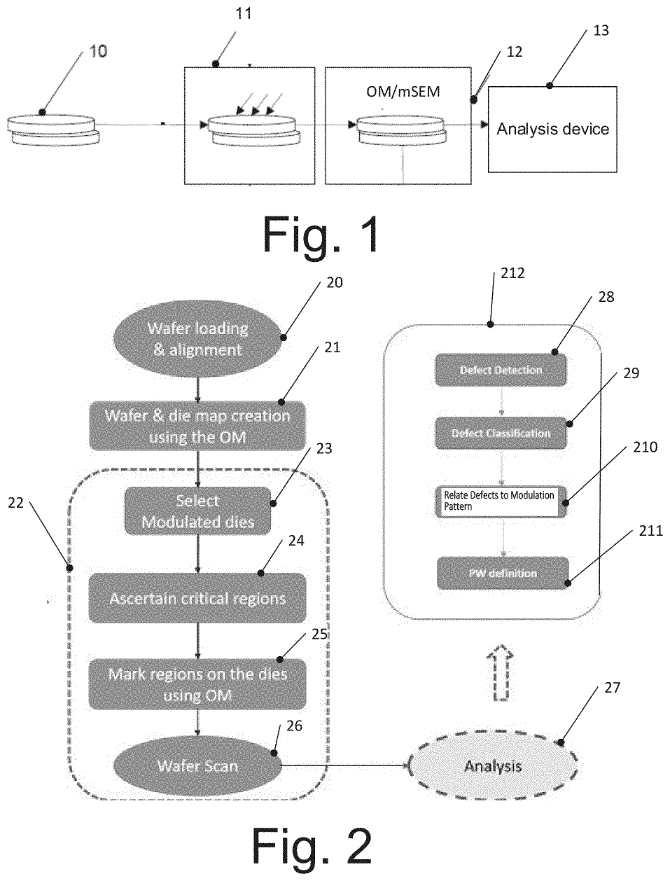

Turning now to the figures, FIG. 1 illustrates a system including a plurality of devices according to some embodiments, and FIG. 2 is a flowchart illustrating a method according to some embodiments. The method shown in FIG. 2 may be implemented using the apparatus of FIG. 1, and for clearer understanding the apparatus of FIG. 1 and the method of FIG. 2 will be described together. Nevertheless, it is to be understood that this is only for better understanding, and method and apparatus may be implemented independently from each other.

In FIG. 1, one or more semiconductor wafers 10 are provided to be used as the above-mentioned process window wafer(s) for process window determination. In one or more processing devices 11, processing including photolithography is performed on a plurality of dies on wafer(s) 10 with varying conditions, in particular, varying focus and dose (light intensity over time) by a lithography scanner or similar device. Other processing may including etching, layer deposition, ion implantation etc. This may be performed as in conventional approaches for process window wafer fabrication and will therefore not be described in detail. It should be noted that while photolithography parameters like focus and dose will be used as main example for process parameters below, techniques discussed herein may also be applied to other process parameters like etching parameters, ion implantation parameters, layer deposition parameters and the like, i.e. parameters for all process steps used for manufacturing a semiconductor device.

At 20 in FIG. 2, the thus processed process window wafer 10 is loaded into an inspection system 12. Inspection system 12 includes an optical microscope (OM) or other optical tool. As an optical microscope, a bright field microscope, a dark field microscope or both may be used. In the following, the term “optical tool” will be used to refer to all these possibilities. An optical tool, as used herein, is a tool using light for imaging, in particular light in the visible range. In contrast thereto, devices that use charged particle beams like electron beams as primary radiation and are not considered optical tools in this sense. Furthermore, inspection system 12 includes a multi-beam scanning electron microscope (mSEM). An mSEM, similar to a usual scanning electron microscope, uses charged particles, in particular electrons, as primary radiation and the image is formed based on secondary particles or radiation emitted from the wafer in response to the irradiation with the primary radiation, i.e. the charged particle beams. The secondary radiation may be in the form of secondary electrons or back scattered charged particles, or electromagnetic radiation such as light or x-rays. The composition, energy and angle of the secondary radiation can be controlled by the energy of the primary radiation and is an indication of the material composition and surface quality of the wafer surface scan.

In the mSEM, instead of using a single beam, the wafer is irradiated by an array of charged particle beams. In the following, electron beams are used as examples. In this case, the mSEM may use 80 or more, in particular up to 10.000 electron beams, as primary radiation. Each electron beam is typically separated by a distance of between 1 and 200 μm from its next neighboring electron beam. For example, the mSEM may have 100 separated electron beams, arranged on a hexagonal array, with the electron beams separated by a distance of 10 μm. These electron beams are scanned in parallel over an object, in this case the wafer, forming an image patch of for example 110 μm diameter. After acquisition of the image patch, a substrate or wafer stage is moved to a next patch position and the image of the next patch is obtained by again scanning of the electron beam array. Thereby, a high resolution image with below 5 nm resolution can be formed by stitching multiple image patches together. It is also possible to acquire high resolution images for specific locations on a wafer, for example for specific locations identified by the optical tool, as will be explained further below. With an mSEM, a fast scanning of a wafer surface is possible, and therefore it is well-suitable for wafer metrology with a high throughput with high resolution of down to a few nanometers, for example above-mentioned 5 nm. The throughput may depend on resolution and the number of beams used. For 100 beams, typical examples of throughput are 3.5. mm²/min (square millimeter per minute), or up to 10 mm²/min. With increasing number of beams, for example with 100×100 beams, the throughput can go up to more than 300 mm²/min, or even more than 500 mm²/min, or even exceed 1000 mm²/min. As will be explained below, by using an mSEM in some embodiments multiple iterations between an optical tool like an optical microscope and a conventional SEM as described above in the background portion may be avoided.

Operation of inspection system 12 will now be further described referring to FIG. 2. As already mentioned, at 20 a wafer is loaded into inspection system 12. In inspection system 12, the wafer is aligned, i.e. such that the orientation of the wafer is well-defined so that a correlation between the result of the inspection and the processing made in processing devices 11 may be made.

Then, at 21, using the optical tool a wafer and die map are created, i.e. the locations of the different dies (which, as explained above, were treated in different ways regarding for example focus and dose in processing device 11) are ascertained. Next, steps 23 to 26 follow in a block 22. In contrast to conventional implementation, in some embodiments, each step 23 to 26 is performed only once, i.e. the method does not involve “jumping back” to previous steps in some embodiments. In particular, in some embodiments, as will be explained next, first steps using the optical tool are performed, and then a scanning with the mSEM is performed, without jumping back and forth between these two examination modalities.

At 23, the method includes selecting modulated dies using the optical microscope. Modulated dies are those which are subjected to different lithography conditions like different dose or focus positions during the processing in processing device 11.

At 24, critical regions are defined in the selected dies. Ascertaining or defining critical regions may be done in various ways, for example based on historical knowledge or based on guidance from manufacturers of semiconductor devices, i.e. users of inspection system 12 and the method shown in FIG. 2 or customers buying inspection system 12 for their manufacturing of semiconductor devices.

Critical regions are regions where structures typically have the smallest space/width combination, and therefore it is desirable to observe them closely. Such critical regions may be regions where certain structures like dense logic structures, memory structures like SRAM structures etc. are implemented. This is also an example for historical knowledge, i.e. from past experience it is known that such regions tend to be critical in terms of processing window definition. In some embodiments, such regions may be regions which go to the limit of the respective technology used. For example, when introducing a new design based e.g. on a 5 nm technology (also referred to as “5 nm node”), in many device designs only a few regions of the device will actually make us of such small structures. Other regions will be implemented with spaces and widths also possible in previous technologies, e.g. 7 nm technology or larger, where process parameters may be well understood. In such cases, the regions actually using the limits of the technology used may be identified as critical regions. A further example for historical knowledge is a knowledge that certain pattern or shapes found in a design are critical, which may all for example be known from previous designs or regions which contain minimum space or minimum width patterns. Width refers to the dimension of structures (device or interconnect structures), usually formed by polygons in the design, and space relates to the separation between such structures, e.g. between the polygons.

Guidance from the manufacturers or designers may come from various sources. Various examples are given below:
Optical proximity correction (OPC) or optical rule check (ORC) simulation data based on OPC models. OPC is a method of design compensation to counter the impacts of diffraction/interference while fabricating masks used for lithography. During the process, CAD (Computer aided Design) simulations are done to see if there are any marginalities that are desirably monitored while manufacturing, i.e. where an ORC has to be performed.
Design rule check (DRC) critical structures, where DRC ensures the manufacturability of the design and therefore is involved in manufacturing structures. All designs are expected to be DRC clean before they could even be used for OPC/photomask fabrication, i.e. are expected to have passed the design rule check. From this design rule check, critical regions may be known. For example, during the design process, it is desirable for the design to pass the DRC. Some parts of the design may turn out to be critical during the DRC, for example barely passing the DRC. Such regions may be identified as critical regions.
A further source may be device performance. There are cases where certain structures are monitored based on the criticality of the device they are part of. In such cases, even minor variations of the critical dimensions may impact the performance of the devices in a significant way.
Process-based weak spots. Semiconductor process tools typically have their own defect signatures. Even if utmost care is taken using tools like etch tools, chemical mechanical polishing tools, etc., zero damage cannot be ensured. Also, sometimes new tools are introduced, and it is desirable for them to be characterized.
Information regarding critical regions may also be obtained from the design of the device, in particular, CAD (computer aided design)-based, or based on critical regions of masks used, e.g. based on photomask design. For example, the above-mentioned regions where structures are at or near the limit of the technology used (e.g. 5 nm technology) may be identified based on the design of the device.
   At 25, these critical regions are marked using the optical microscope, i.e. information is provided where the critical regions are located. It should be noted that the actions performed at 24 and at 25 may also be performed concurrently, for example by marking each critical region after it has been ascertained. Furthermore, it should be noted that the actions at 23 to 25 may be performed based on user input and/or may be performed automatically for example using image analysis (for example patterns having minimum width or space or patterns corresponding to patterns which are historically known to be critical may be identified by automatic image analysis). Critical regions may also be identified in automatically based on design information, and then the this identified regions may be defined in the image based on image analysis approaches to find the regions identified in the design also in the actual image. For example, this automatic identification in the image may be based on shape primitives of shapes in the design, as described for example in US patent application US 2017/0186151 A1.

At 26, then a scanning of the thus identified critical regions using an mSEM is performing. By using an mSEM, a high throughput can be performed. In particular, as an mSEM uses multiple beams as discussed above, in embodiments larger areas may be captured in the same time which enables identifying defects that are region-dependent. For example, certain process steps during device processing when parameters are selected wrongly or otherwise causing problems can leave a footpring in certain regions of the device which are vulnerable to problems in these process steps. Examples for such process steps include etching (where over-etching may cause such a footprint) or chemical-mechanical polishing (CMP). As mSEM can offer a high throughput compared to conventional SEM, it is possible to scan larger regions sufficiently fast and therefore enable detection of such region-dependent defects. In contrast, it is difficult to capture such defects using the convention work flow based on single beam scanning electron microscopes. Moreover, as significantly more data can be covered with the mSEM, in contrast to conventional approaches there is no need to identify only a few locations for SEM.

It is desirable that only a single wafer scan run is performed using the method of FIG. 2 at 20 as all regions have been marked at 25, and due to the throughput of the mSEM all such regions may be scanned.

In other words, the various acts and events at 22 are performed in one image acquisition run without iterations in some implementations.

Next, the mSEM image thus acquired by the wafer scan at 26 is analyzed at 27. An example analysis is shown at 212 in FIG. 2. Generally, any conventional approaches for analyzing scanning electron microscopy images may be employed. For the analysis at 27, in FIG. 1 an analysis device 13 is used. Analysis device 13 typically may be implemented using a computer which may perform image analysis and may also allow visual displaying the images acquired at 22 (optical images and mSEM images). Nevertheless, in other embodiments specific hardware components may be used additionally or alternatively, for example graphic processors, application-specific integrated circuits (ASICs), field programmable gate arrays (FPGAs) and the like. Analysis device 13 may also be used to control inspection system 12 in some embodiments, for example to perform the automatic determination of critical regions mentioned above. In other embodiments, inspection system 12 may include a separate controller, which may be in the form of a computer and/or specific hardware, similar to the implementation of analysis device 12.

At 28, the example analysis includes a defect detection. In other words, defects in the structures of the various dies are identified based on the scanning electron microscopy images acquired at 26. By using the mSEM larger areas may be scanned, which allows efficient capture of defects. The defects may be identified using image analysis approaches. Alternatively or additionally, defects may be identified by a human user in the images. At 29, the defects are classified regarding the type of defects (for example on the basis of ‘design/pattern’, ‘defect-type’ (e.g open, bridge etc), etc).

At 210, the detected and classified defects are related to the modulation pattern, i.e. to the variation of process parameters like dose and focus. Also, a root cause analysis may be performed to determine how these defects are caused by variations of dose and focus.

Additionally or alternatively to the analysis described above, the analysis may be performed from a critical dimension point of view.

In this case, the analysis 27 may include measuring critical dimensions of critical structures for ever combination of dose and focus used. The critical structures may be defined by the designer of the respective chip. Then, the analysis may include ascertaining the best critical dimension values among the measured ones for the intended design and performance, and identifying those combinations of dose and focus which lead to these critical dimension values.

In both cases, the analysis then at 211 may include defining a process window.

The process of FIG. 2 may be repeated for different layers of a planned semiconductor device, i.e. for each layer dies may be formed with different process parameters, and then the corresponding dies may be examined.

In the above-described embodiments, a process window wafer was used with a plurality of dies, where process parameters were varied between dies. In other embodiments, instead a plurality of wafers may be provided, where process parameters are varied between wafers. In this case, the actions at 20, 21 and 22 in FIG. 2 are performed for each wafer, without the identification of different dies, and in the analysis the mSEM results for all wafers are examined. The two approaches may also be combined, i.e. different wafers with different dies.

Implementations of the subject matter and the functional operations described in this specification can be implemented in digital electronic circuitry, in tangibly-embodied computer software or firmware, in computer hardware, including the structures disclosed in this specification and their structural equivalents, or in combinations of one or more of them. Implementations of the subject matter described in this specification can be implemented as one or more computer programs, i.e., one or more modules of computer program instructions encoded on a tangible program carrier for execution by, or to control the operation of, a processing device. Alternatively or in addition, the program instructions can be encoded on a propagated signal that is an artificially generated signal, e.g., a machine-generated electrical, optical, or electromagnetic signal that is generated to encode information for transmission to suitable receiver apparatus for execution by a processing device. A machine-readable medium can be a machine-readable storage device, a machine-readable storage substrate, a random or serial access memory device, or a combination of one or more of them.

The term “processing device” encompasses all kinds of apparatus, devices, and machines for processing information, including by way of example a programmable processor, a computer, or multiple processors or computers. The apparatus can include special purpose logic circuitry, e.g., an FPGA (field programmable gate array) or an ASIC (application specific integrated circuit) or RISC (reduced instruction set circuit). The apparatus can also include, in addition to hardware, code that creates an execution environment for the computer program in question, e.g., code that constitutes processor firmware, a protocol stack, an information base management system, an operating system, or a combination of one or more of them.

A computer program (which may also be referred to as a program, software, a software application, a script, or code) can be written in any form of programming language, including compiled or interpreted languages, or declarative or procedural languages, and it can be deployed in any form, including as a stand alone program or as a module, component, subroutine, or other unit suitable for use in a computing environment. A computer program may, but need not, correspond to a file in a file system. A program can be stored in a portion of a file that holds other programs or information (e.g., one or more scripts stored in a markup language document), in a single file dedicated to the program in question, or in multiple coordinated files (e.g., files that store one or more modules, sub programs, or portions of code). A computer program can be deployed to be executed on one computer or on multiple computers that are located at one site or distributed across multiple sites and interconnected by a communication network.

The processes and logic flows described in this specification can be performed by one or more programmable computers executing one or more computer programs to perform functions by operating on input information and generating output. The processes and logic flows can also be performed by, and apparatus can also be implemented as, special purpose logic circuitry, e.g., an FPGA (field programmable gate array) or an ASIC (application specific integrated circuit) or RISC.

Computers suitable for the execution of a computer program include, by way of example, general or special purpose microprocessors or both, or any other kind of central processing unit. Generally, a central processing unit will receive instructions and information from a read only memory or a random access memory or both. The essential elements of a computer are a central processing unit for performing or executing instructions and one or more memory devices for storing instructions and information. Generally, a computer will also include, or be operatively coupled to receive information from or transfer information to, or both, one or more mass storage devices for storing information, e.g., magnetic, magneto optical disks, or optical disks. However, a computer need not have such devices. Moreover, a computer can be embedded in another device, e.g., a mobile telephone, a smartphone or a tablet, a touchscreen device or surface, a personal digital assistant (PDA), a mobile audio or video player, a game console, a Global Positioning System (GPS) receiver, or a portable storage device (e.g., a universal serial bus (USB) flash drive), to name just a few.

Computer readable media (e.g., one or more machine readable hardware storage devices) suitable for storing computer program instructions and information include all forms of non volatile memory, media and memory devices, including by way of example semiconductor memory devices, e.g., EPROM, EEPROM, and flash memory devices; magnetic disks, e.g., internal hard disks or removable disks; magneto optical disks; and CD ROM and (Blue Ray) DVD-ROM disks. The processor and the memory can be supplemented by, or incorporated in, special purpose logic circuitry.

To provide for interaction with a user, implementations of the subject matter described in this specification can be implemented on a computer having a display device, e.g., a CRT (cathode ray tube) or LCD (liquid crystal display) monitor, for displaying information to the user and a keyboard and a pointing device, e.g., a mouse or a trackball, by which the user can provide input to the computer. Other kinds of devices can be used to provide for interaction with a user as well; for example, feedback provided to the user can be any form of sensory feedback, e.g., visual feedback, auditory feedback, or tactile feedback; and input from the user can be received in any form, including acoustic, speech, or tactile input. In addition, a computer can interact with a user by sending documents to and receiving documents from a device that is used by the user; for example, by sending web pages to a web browser on a user's client device in response to requests received from the web browser.

Implementations of the subject matter described in this specification can be implemented in a computing system that includes a back end component, e.g., as an information server, or that includes a middleware component, e.g., an application server, or that includes a front end component, e.g., a client computer having a graphical user interface or a Web browser through which a user can interact with an implementation of the subject matter described in this specification, or any combination of one or more such back end, middleware, or front end components. The components of the system can be interconnected by any form or medium of digital information communication, e.g., a communication network. Examples of communication networks include a local area network (“LAN”) and a wide area network (“WAN”), e.g., the Internet.

The computing system can include clients and servers. A client and server are generally remote from each other and typically interact through a communication network. The relationship of client and server arises by virtue of computer programs running on the respective computers and having a client-server relationship to each other. In another example, the server can be in the cloud via cloud computing services.

Although specific embodiments have been illustrated and described herein, it will be appreciated by those of ordinary skill in the art that a variety of alternate and/or equivalent implementations may be substituted for the specific embodiments shown and described without departing from the scope of the present disclosure. The disclosure is intended to cover any adaptations or variations of the specific embodiments discussed herein. Therefore, it is intended that the scope be limited only by the claims and the equivalents thereof.

1. A method, comprising:
using an optical tool to define critical regions on a plurality of dies of a wafer, the plurality of dies comprising structures, different dies having been manufactured using different process parameters; and
using a plurality of scanning beams simultaneously to scan the critical regions, the plurality of scanning beams being generated by a multi-beam scanning electron microscope.

2. The method of claim 1, wherein defining critical regions comprises creating a die map on the wafer.

3. The method of claim 1, wherein defining critical regions is based on historical knowledge about the structures.

4. The method of claim 1, wherein defining critical regions is based on information from a manufacturer or designer of the structures.

5. The method of claim 1, wherein defining critical regions is based on optical proximity correction data.

6. The method of claim 5, wherein defining critical regions is based on simulation data based on an optical proximity correction model.

7. The method of claim 1, wherein defining critical regions is based on computer-aided design data.

8. The method of claim 1, wherein defining critical regions is based on photolithography mask data.

9. The method of claim 1, wherein the process parameters comprise photolithography parameters.

10. The method of claim 1, further comprising defining a process window based on a result of scanning the critical regions.

11. The method of claim 10, wherein defining the process window comprises at least one member selected from the group consisting of defect detection, defect classification, correlation of detected defects with varying process parameters, and detecting of region-dependent defects.

12. The method of claim 10, wherein defining the process windows comprises measuring critical dimensions.

13. The method of claim 1, wherein:
the structures of the dies comprise a plurality of layers;
the plurality of layers comprises a first layer;
for the first layer, defining the critical regions and scanning the critical regions are performed without an additional step of defining the critical regions or scanning the critical regions occurring therebetween.

14. One or more machine-readable hardware storage devices, comprising:
instructions that are executable by one or more processing devices to perform operations comprising the method of claim 1.

15. A system, comprising:
one or more processing devices; and
one or more machine-readable hardware storage devices comprising instructions that are executable by the one or more processing devices to perform operations the method of claim 1.

16. An inspection system, comprising:
an optical tool configured to define critical regions in a wafer including a plurality of dies comprising structures, different dies manufactured via different process parameters; and
a multi-beam scanning electron microscope configured to simultaneously use a plurality of scanning beams to scan the defined critical regions.

17. The system of claim 16, further comprising an analysis device configured to define a process window based on an analysis of a result of scanning the critical regions.

18. The system of claim 17, further comprising an analysis device configured to define a process window based on at least one member selected from the group consisting of defect detection, defect classification, correlation of detected defects with the varying process parameters, and measuring critical dimensions.

19. The system of claim 16, wherein the optical tool is configured to automatically define the critical regions based on design data.

20. A method, including:
using an optical tool to define critical regions on a plurality of wafers, the wafers comprising structures, different wafers manufactured using different process parameters; and
using a plurality of scanning beams simultaneously to scan the critical regions, the plurality of scanning beam being generated by a multi-beam scanning electron microscope.
